(19) United States
(12) Patent Application Publication
(10) Pub. No.: US 2006/0269796 A1
(43) Pub. Date: Nov. 30, 2006

(54) Magnetic recording medium, method of manufacturing the same, and magnetic recording apparatus

(75) Inventor: Hiroyuki Hyodo, Ome-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/441,178

(22) Filed: May 26, 2006

(30) Foreign Application Priority Data
May 27, 2005 (JP) 2005-155851

(51) Int. Cl. G11B 5/65; B05D 5/12; C23C 14/00

(52) U.S. Cl. 428/833.2; 428/836.2; 428/836.3; 204/192.2; 427/130

(57) ABSTRACT

According to one embodiment, a magnetic recording medium has a non-magnetic substrate, patterns of magnetic recording layer separated from one another and a non-magnetic material filled in between the patterns of the magnetic recording layer which are formed on the non-magnetic substrate, a metal film formed on the patterns of magnetic recording layer and the non-magnetic material, and a carbon protective film formed on the metal film.

### CROSS-REFERENCE TO RELATED APPLICATIONS

This application is based upon and claims the benefit of priority from Japanese Patent Application No. 2005-155851, filed May 27, 2005, the entire contents of which are incorporated herein by reference.

### BACKGROUND

1. Field

One embodiment of the present invention relates to a magnetic recording medium having discrete tracks, a method of manufacturing the same, and a magnetic recording apparatus.

2. Description of the Related Art

Improvement of recording density is perpetually required for magnetic recording apparatuses such as hard disk drives. As one solution for improving recording density, a discrete track type magnetic recording medium has been proposed in which recording tracks are separated from one another thereby preventing the magnetic field of the recording head from being exerted on an adjacent recording track (side fringing).

Such a magnetic recording medium having discrete tracks has a structure in which a magnetic recording layer is deposited on a non-magnetic substrate and processed into patterns separated from one another, a non-magnetic material is filled in between the patterns of the magnetic recording layer and then is planarized, a carbon protective film is formed on the surface thereof by plasma-enhanced CVD, and a lubricant is applied to the surface of the carbon protective film. The reason why the non-magnetic material is filled in between the patterns of the magnetic recording layer and then is planarized, as described above, is to ensure flying stability of the head slider over the magnetic recording medium.

In accordance with the study of the present inventor, however, it has been found that, in the discrete track type magnetic recording medium having the structure as described above, there is such a problem that a carbon protective film with satisfactory quality cannot be formed in some cases and thus sufficient protective performance cannot be provided.

Conventionally, there is proposed a magnetic recording medium comprising a granular magnetic layer prepared by dispersing magnetic grains in a metal oxide, a carbon protective film, and a metal intermediate layer provided between the granular magnetic layer and the carbon protective film (Jpn. Pat. Appln. KOKAI Publication No. 2001-43526). This technique is to solve a problem that, when the carbon protective film is deposited by spattering, oxygen beaten out of the metal oxide of the granular magnetic layer is combined with carbon to produce oxidized carbon, leading to deterioration of the quality of the protective film. In the above technique, provision of the metal intermediate layer between the granular magnetic layer and the carbon protective film prevents the oxidized carbon from being produced, making it possible to prevent the quality of the carbon protective film from being deteriorated.

However, the prior art does not relate to a magnetic recording medium having discrete tracks separated by grooves and also the method of depositing a carbon protective film is not plasma-enhanced CVD. Therefore, the prior art cannot solve the problem of difficulty in forming a carbon protective film with satisfactory quality with which the inventor has been confronted.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a cross-sectional view of a magnetic recording medium having discrete tracks according to an embodiment of the present invention;

FIGS. 2A, 2B, 2C, 2D, 2E, 2F, 2G, 2H, 2I and 2J are cross-sectional views showing a method of manufacturing the magnetic recording medium of FIG. 1;

FIG. 3 is a plan view showing a state that the electrodes are brought into contact with the disk when a bias voltage is applied to the substrate in depositing a carbon protective film;

FIG. 4 is a cross-sectional view showing a state that the electrodes are brought into contact with the disk as in FIG. 3; and

FIG. 5 is a perspective view of a magnetic recording apparatus according to an embodiment of the present invention.

### DETAILED DESCRIPTION

Various embodiments according to the invention will be described hereinafter with reference to the accompanying drawings. In general, according to one embodiment of the present invention, there is provided a magnetic recording medium comprising: a non-magnetic substrate; patterns of magnetic recording layer separated from one another and a non-magnetic material filled in between the patterns of the magnetic recording layer which are formed on the non-magnetic substrate; a metal film formed on the patterns of magnetic recording layer and the non-magnetic material; and a carbon protective film formed on the metal film. According to another embodiment of the present invention, there is provided a method of manufacturing a magnetic recording medium comprising: depositing a magnetic recording layer on a non-magnetic substrate, and then patterning the magnetic recording layer into patterns separated from one another; filling a non-magnetic material in between the patterns of the magnetic recording layer, and then planarizing the non-magnetic material so as to expose the patterns of the magnetic recording layer; depositing a metal film on the patterns of the magnetic recording layer and the non-magnetic material; and depositing a carbon protective film on the metal film while applying a bias voltage to the substrate.

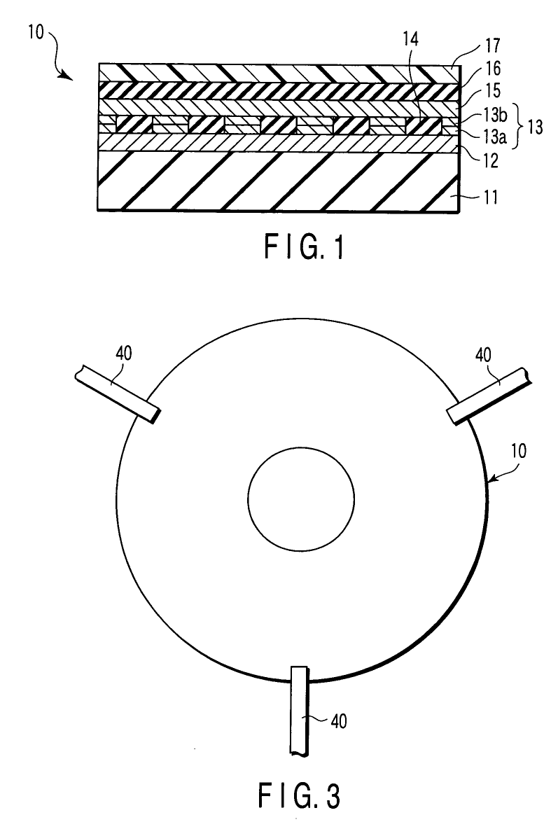

According to an embodiment, FIG. 1 shows a cross-sectional view of a magnetic recording medium (magnetic disk 10) having discrete tracks according to an embodiment of the present invention. An underlayer 12 is formed on a non-magnetic substrate 11. A magnetic recording layer 13 including two or more magnetic layers 13a and 13b is formed on the underlayer 12. The magnetic recording layer 13 is patterned so as to form recording tracks separated by recesses. A non-magnetic material 14 is filled into the recesses between the patterns of the magnetic recording layer 13. A metal film 15 and a carbon protective film 16 are formed on the patterns of the magnetic recording layer 13 and the non-magnetic material 14. A lubricant 17 is applied to the carbon protective film 16.

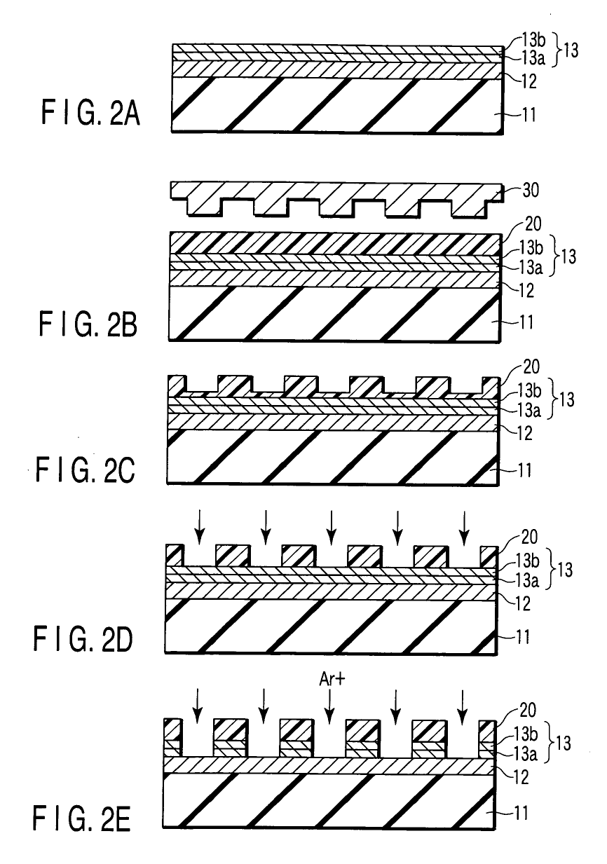

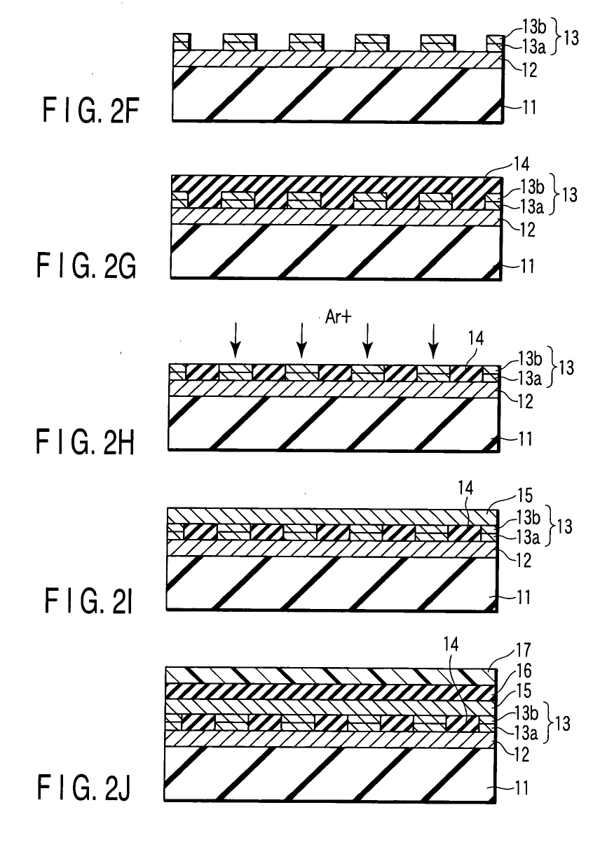

A method of manufacturing the magnetic recording medium shown in FIG. 1 will be described with reference to FIGS. 2A, 2B, 2C, 2D, 2E, 2F, 2G, 2H, 2I and 2J.

As shown in FIG. 2A, the underlayer 12 is deposited by spattering on the non-magnetic substrate 11. The magnetic recording layer 13 is formed by depositing, for example, two-layered magnetic layers 13a and 13b on the underlayer 12. Each of the underlayer 12 and the magnetic recording layer 13 is made to have a structure and thickness so as to achieve optimal electromagnetic transducing characteristics. In perpendicular magnetic recording, for example, a soft underlayer and a crystal orientation control layer are used as the underlayer 12, and a magnetic layer with perpendicular anisotropy is used as the magnetic recording layer 13. Although the magnetic recording layer 13 is formed of two-layered magnetic layers 13a and 13b in two layers in FIG. 2A, the magnetic recording layer 13 is formed of three or more layers of stacked magnetic layers.

The magnetic recording layer 13 formed of two or more magnetic layers include, for example, at least one magnetic layer in which grains containing Co as a main component and Pt are dispersed in a metal oxide and at least one another magnetic layer containing Co as a main component and Cr but not containing a metal oxide, as described in Jpn. Pat. Appln. KOKAI Publication No. 2004-3109150. Examples of the metal oxide include an oxide of a non-magnetic metal selected from the group consisting of Cr, Si, Ta, Al and Ti.

Here, the magnetic layer containing the metal oxide (so-called granular film) has an advantage that it is effective to reduce the size of magnetic grains and isolate the magnetic grains. However, forming the magnetic recording layer using the magnetic layer containing the metal oxide alone brings excessively high coercivity, making it difficult to provide satisfactory read/write characteristics. On the other hand, forming the magnetic recording layer 13 using a magnetic layer containing a metal oxide in combination with another magnetic layer not containing a metal oxide makes it possible to improve thermal fluctuation resistance and read/write characteristics.

As shown in FIG. 2B, a resist 20 is applied to the magnetic recording layer 13. A stamper 30 prepared in advance is arranged on the resist 20. As shown in FIG. 2C, imprinting is carried out by pressing the stamper 30 against the resist 20, and then the stamper is removed, thereby transferring the patterns corresponding to recording tracks, tracking servo signals, address data signals and read clock signals to the resist 20. It should be noted that forming patterns on the resist 20 can also be accomplished by carrying out exposure through a mask having desired patterns and development.

As shown in FIG. 2D, resist residues remaining on the bottoms of the recesses of the patterned resist 20 are removed by reactive ion etching (RIE) using oxygen gas. As shown in FIG. 2E, the magnetic recording layer 13 is etched by Ar ion milling to form the patterns of the magnetic recording layer 13 corresponding to recording tracks, tracking servo signals, address data signals and read clock signals.

As shown in FIG. 2F, the resist is peeled off by oxygen RIE. As shown in FIG. 2G, SiO₂ as the non-magnetic material 14 is spattered so as to fill SiO₂ into the recesses between the patterns of the magnetic recording layer 13, and to deposit SiO₂ on the patterns of the magnetic recording layer 13. It should be noted that another non-magnetic material such as carbon (C) may be used in place of SiO₂. As shown in FIG. 2H, the non-magnetic material (SiO₂) which is excessively deposited is removed by Ar ion milling so as to expose the patterns of the magnetic recording layer 13, thereby planarizing the surface thereof. At this time, etch-back is carried out, for example, until the surface of the patterns of the magnetic recording layer 13 is over-etched by about 1 to 5 nm.

As shown in FIG. 2I, the metal film 15 is deposited on the patterns of the magnetic recording layer 13 and the non-magnetic material 14. As the metal film 15, a magnetic material having the same composition as that of an uppermost magnetic layer of the two or more magnetic layers included in the magnetic recording layer 13 may be used. In this manner, if the metal film 15 having a thickness of 1 to 5 nm which compensates the thickness overetched in FIG. 2H is formed again by using the magnetic metal material having the same composition as that of the uppermost magnetic layer, deterioration in the magnetic characteristics which may be brought about in etch-back process can be suppressed. It should be noted that, even if a magnetic material having a composition different from that of the uppermost magnetic layer is used as the meal layer 15, deterioration in the magnetic characteristics can be suppressed. Although the details will be described hereinafter, a non-magnetic metal material, for example, Cr or Ti may be used as the metal film 15 in order to ensure the conductivity of the substrate such that a bias voltage can be desirably applied to the substrate in depositing the carbon protective film.

As shown in FIG. 2J, a carbon protective film 16 made of diamond-like carbon (DLC) is deposited on the metal film 15. Further, the lubricant 17 is applied to the carbon protective film 16. Thus, a magnetic recording medium (discrete track medium) can be manufactured.

Here, to form a carbon protective film, a deposition method such as plasma-enhanced chemical vapor deposition (PECVD) or ion beam deposition (IBD) may be used. In order to obtain a carbon protective film with good quality by such a deposition method, it is necessary to apply a bias voltage to the substrate. More specifically, as shown in FIG. 3, a substrate bias voltage is applied by bringing electrodes 40 into contact with several points at the edge portion of the disk 10.

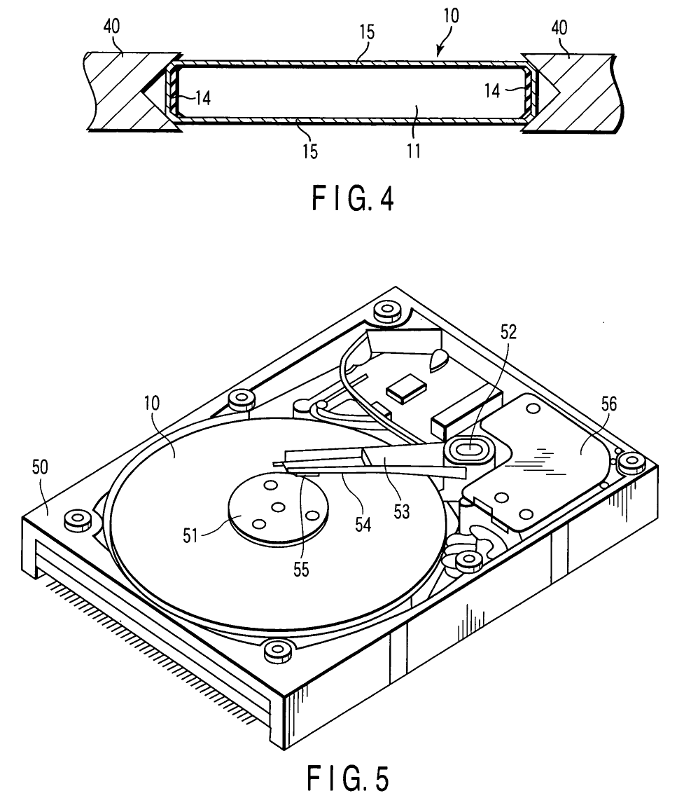

The state of contact between the disk 10 and the electrodes 40 will be described with reference to a cross-sectional view shown in FIG. 4. In this drawing, films formed on the non-magnetic substrate 11 of the disk 10 is not shown in detail, and only the non-magnetic material 14, on the surface of the non-magnetic substrate 11, and the metal film 15 are shown. As described above, the non-magnetic material 14 is etched-back by Ar ion milling in the step of FIG. 2H. However, it is difficult to completely remove the non-magnetic material 14 from the edge portion of the disk 10, and thus a part of the non-magnetic material 14 inevitably remains on that portion.

Because a carbon protective film is deposited immediately after the etch-back step in the prior art, the electrodes 40 are made to be in contact with the non-magnetic material 14 remaining on the edge portion of the disk 10, making it impossible to normally apply a bias voltage to the substrate. As a result, this brings about deterioration in the quality of the carbon protective film.

To the contrary, in the embodiment of the present invention, the metal film 15 is formed on the surface of the disk 10 in the process of FIG. 2I, making it possible to ensure conductivity between the electrodes 40 and the meal film 15. Consequently, a bias voltage can be satisfactorily applied to the substrate, preventing the carbon protective film from being deteriorated in quality.

A structure of a magnetic recording apparatus 50 in which the magnetic recording medium described above (discrete track medium) is installed will be described with reference to FIG. 5. The magnetic disk 10 is mounted on a spindle 51 and is rotated by the motor that responds to control signals from a driver control unit (not shown). A pivot 52 is provided in the vicinity of the magnetic disk 10. An actuator arm 53 is attached to the pivot 52 so as to be pivotally rotated. A suspension 54 is attached at the distal end of the actuator arm 53. A head slider 55 is supported by the suspension 54. A magnetic head including a write pole and a magnetoresistive element serving as a read element is incorporated in the vicinity of the distal end of the head slider 55. A voice coil motor 56, a type of a linear motor, is provided to the proximal end of the actuator arm 53. The voice coil motor 56 is constituted by a coil wound up on a bobbin portion of the proximal portion of the actuator arm 53, and a magnetic circuit including a permanent magnet and a counter yoke which are arranged to face each other so as to sandwich the coil. The actuator arm 53 is actuated by the voice coil motor 56. When the magnetic disk 10 is rotated, the air bearing surface (ABS) of the head slider 55 is held so as to have a predetermined flying height from the surface of the magnetic disk 10. Thus, write and read of data to and from the magnetic disk 10 are performed by the magnetic head.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.
What is claimed is:

1. A magnetic recording medium comprising:
a non-magnetic substrate;
patterns of magnetic recording layer separated from one another and a non-magnetic material filled in between the patterns of the magnetic recording layer which are formed on the non-magnetic substrate;
a metal film formed on the patterns of magnetic recording layer and the non-magnetic material; and
a carbon protective film formed on the metal film.

2. The magnetic recording medium according to claim 1, wherein the patterns of the magnetic recording layer form discrete tracks.

3. The magnetic recording medium according to claim 1, wherein the magnetic recording layer comprises two or more magnetic layers.

4. The magnetic recording medium according to claim 3, wherein the metal film is formed of a magnetic metal material having the same composition as that of an uppermost magnetic layer included in the magnetic recording layer.

5. The magnetic recording medium according to claim 3, wherein the metal film is formed of a magnetic metal material having a composition different from that of an uppermost magnetic layer included in the magnetic recording layer.

6. The magnetic recording medium according to claim 3, wherein the two or more magnetic layers includes at least one magnetic layer in which grains containing Co as a main component and Pt are dispersed in a metal oxide and at least one another magnetic layer containing Co as a main component and Cr but not containing a metal oxide.

7. The magnetic recording medium according to claim 6, wherein the metal oxide is formed of an oxide of a metal selected from the group consisting of Cr, Si, Ta, Al and Ti.

8. The magnetic recording medium according to claim 1, wherein the metal film is formed of a non-magnetic metal material.

9. The magnetic recording medium according to claim 8, wherein the non-magnetic metal material is selected from the group consisting of Cr and Ti.

10. A method of manufacturing a magnetic recording medium, comprising:
depositing a magnetic recording layer on a non-magnetic substrate, and then patterning the magnetic recording layer into patterns separated from one another;
filling a non-magnetic material in between the patterns of the magnetic recording layer, and then planarizing the non-magnetic material so as to expose the patterns of the magnetic recording layer;
depositing a metal film on the patterns of the magnetic recording layer and the non-magnetic material; and
depositing a carbon protective film on the metal film while applying a bias voltage to the substrate.

11. The method according to claim 10, wherein the magnetic recording layer is patterned into discrete tracks.

12. The method according to claim 10, wherein the magnetic recording layer comprises two or more magnetic layers.

13. The method according to claim 12, wherein a magnetic metal material having the same composition as that of an uppermost magnetic layer included in the magnetic recording layer is deposited as the metal film.

14. The method according to claim 12, wherein a magnetic metal material having a composition different from that of an uppermost magnetic layer included in the magnetic recording layer is deposited as the metal film.

15. The method according to claim 12, wherein the two or more magnetic layers includes at least one magnetic layer in which grains containing Co as a main component and Pt are dispersed in a metal oxide and at least one another magnetic layer containing Co as a main component and Cr but not containing a metal oxide.

16. The method according to claim 15, wherein the metal oxide is formed of an oxide of a metal selected from the group consisting of Cr, Si, Ta, Al and Ti.

17. The method according to claim 10, wherein a non-magnetic metal material is deposited as the metal film.

18. The method according to claim 17, wherein the non-magnetic metal material is selected from the group consisting of Cr and Ti.

19. The method according to claim 17, wherein the carbon protective film is deposited by plasma-enhanced chemical vapor deposition or ion beam deposition.

20. A magnetic recording apparatus comprising: the magnetic recording medium according to claim 1; and a magnetic head.
